(19) United States
(12) Patent Application Publication
(10) Pub. No.: US 2015/0060017 A1
(43) Pub. Date: Mar. 5, 2015

(54) COOLING APPARATUS USING SOLID-LIQUID PHASE CHANGE MATERIAL

(71) Applicant: National Central University, Jhongli City (TW)

(72) Inventors: Te-Yuan CHUNG, Jhongli Ctiy (TW); Hao-Hsuan HUANG, Jhongli Ctiy (TW)

(73) Assignee: National Central University, Jhongli City (TW)

(21) Appl. No.: 14/050,060

(22) Filed: Oct. 9, 2013

(30) Foreign Application Priority Data
Sep. 5, 2013 (TW) 102132053

(51) Int. Cl. H05K 7/20; G06F 1/20

(52) U.S. Cl. CPC H05K 7/2029; G06F 1/20
USPC 165/104.17

(57) ABSTRACT

A cooling apparatus using solid-liquid phase change material (solid-liquid PCM) is disclosed. The cooling apparatus includes a pipeline, a housing enclosing the pipeline, and the solid-liquid PCM filling in an interior of the pipeline and a space between the pipeline and the housing. The solid-liquid PCM can contact a heat source and absorb the heat generated by the heat source, so as to transform from solid state to liquid state. The solid-liquid PCM in the liquid state can circulate inside the pipeline and the space between the pipeline and the housing. Thus, the heat is dissipated by the means of thermal convection. Meanwhile, the heat also can be dissipated through the housing. Therefore, the heat dissipation can be achieved by thermal conduction and heat convection simultaneously.

### BACKGROUND OF THE INVENTION

1. Field of the Invention

The present invention relates to a cooling device. More particularly, the invention relates to a cooling apparatus using phase change material, which is changed from a solid state to a liquid state by absorbing heat, to provide cooling effect.

2. Descriptions of Related Art

In recent years, with the development of technology, electronic products whether it be a CPU module, an IC module, a power chip or an LED lamp, they all require cooling devices to dissipate the excess heat timely. To meet the needs of electronic products for heat dissipation, many different heat dissipation methods have been developed and can be divided into two categories: passive cooling and active cooling. Active cooling, such as water cooling or fan forced convection, requires extra energy to drive the cooling device. However, passive cooling does not require any extra energy. For example, cooling fins may be used to achieve free convection by directly cooling the air, and passive cooling can be also achieved by thermal radiation from the surface of the object.

Active cooling usually provides a better cooling effect. For example, forced convection by a fan can easily achieve an effective heat transfer coefficient of about 1,000 W/m²K. However, using the extra energy to drive the active cooling device also increases the cooling costs. When the driving system of the active cooling device fails, the entire active cooling device will not work as well.

Passive cooling can effectively control the cooling costs because no extra energy is needed, but the cooling effect is poor and very limited for same reason. For example, the effective heat transfer coefficient of free air convection is only about 10 W/m²K. In addition, thermal radiation cooling only works better than thermal conduction and thermal convection when the temperature difference between the heat source and the ambient is big enough. Thus, thermal radiation can only be used as an auxiliary cooling method for general electronic components and cannot provide sufficient cooling effect by itself.

Therefore, how to effectively design a cooling device, which utilizes a passive cooling principle and can effectively improve the cooling effect becomes a goal that is urgently needed to be researched and developed.

### SUMMARY OF THE INVENTION

The invention is a cooling apparatus using solid-liquid phase change material (solid-liquid PCM) to directly absorb heat generated by the heat source as a latent heat for the solid-liquid PCM required during phase change. The solid-liquid PCM would absorb heat and delay the heating rate of the heat source during the temperature rising process of the heat source to ensure that the temperature of the heat source can be maintained under the operating temperature in long term. When the solid-liquid PCM changes to the liquid state, it flows through the pipeline and housing to dissipate heat by thermal convection. Meanwhile, heat would be dissipated outwards by thermal conduction through the housing to improve the cooling effect.

The present invention provides a cooling apparatus using solid-liquid phase change material (solid-liquid PCM), the solid-liquid phase change cooling apparatus making contact with a heat source and comprising: a pipeline having an upper end and a lower end, each of the upper end and the lower end having a diverting opening, respectively; a housing completely enclosing the pipeline without directly making contact with the pipeline, the housing having: an inclined diverting portion tilting towards an off axis direction from a central axis of the housing, each of two opposite ends of the inclined diverting portion having a heat source opening and a connecting portion opening respectively, a cross-sectional area of the connecting portion opening is larger than a cross-sectional area of the heat source opening, a location of the connecting portion opening is lower than locations of the diverting openings, a location of the heat source opening is lower than the location of the connecting portion opening, the heat source being disposed at the heat source opening and covering the heat source opening; a vertical portion connecting to the inclined diverting portion at the connecting opening portion and extending away from the heat source opening; a sealing portion connecting to the vertical portion and covering an opening formed by the vertical portion, a gap being defined between the sealing portion and the pipeline; and a plurality of inner fins connecting to the vertical portion and extending towards the central axis of the housing; and a solid-liquid phase change material filling in an interior of the pipeline and a space between the pipeline and the housing, a melting point of the solid-liquid phase change material being below the operating temperature of the heat source; wherein the solid-liquid phase change material absorbs heat energy generated by the heat source and is changed from a solid state to a liquid state, the solid-liquid phase change material in the liquid state flows from the heat source opening towards the diverting opening, which is close to the connecting portion opening, then flows through the pipeline and out of the diverting opening of the other end of the pipeline, flows into the space between the pipeline and the housing and flows back to the heat source opening with the guide of the inclined diverting portion.

By implementing the present invention, at least the following progressive effects can be achieved:

1. delaying the heating rate of the heat source;
2. dissipating heat by both thermal conduction and thermal convection; and
3. improving the cooling effect.

### BRIEF DESCRIPTION OF THE DRAWINGS

The invention as well as a preferred mode of use, further objectives and advantages thereof will be best understood by reference to the following detailed description of illustrative embodiments when acquire in conjunction with the accompanying drawings, wherein:

FIG. 1 is a perspective view of a cooling apparatus using solid-liquid phase change material of an embodiment in accordance with the present invention;

FIG. 2A is a cross-sectional view along A-A section line of FIG. 1;

FIG. 2B is a cross-sectional view along B-B section line of FIG. 1;

FIG. 2C is a cross-sectional view of the connection between the inner fins and the pipeline of FIG. 2A;

FIG. 3 is a perspective view of another cooling apparatus using solid-liquid phase change material of an embodiment in accordance with the present invention;

FIG. 4A is a cross-sectional view along A′-A′ section line of FIG. 3;

FIG. 4B is a cross-sectional view along B′-B′ section line of FIG. 3;

FIG. 4C is a cross-sectional view of the connection between the inner fins and the pipeline of FIG. 4A;

FIG. 5 is a schematic view of an aspect of inner fins and outer fins of an embodiment in accordance with the present invention;

FIG. 6 is a schematic view of another aspect of inner fins and outer fins of an embodiment in accordance with the present invention; and

FIG. 7 and FIG. 8 are schematics for illustrating the flow direction of the solid-liquid phase change material in a solid-liquid phase change apparatus of an embodiment in accordance with the present invention, respectively.

### DETAILED DESCRIPTION OF THE INVENTION

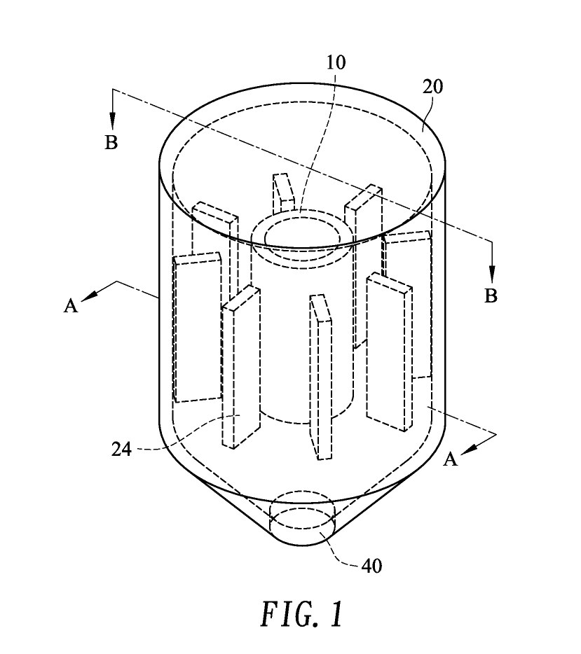

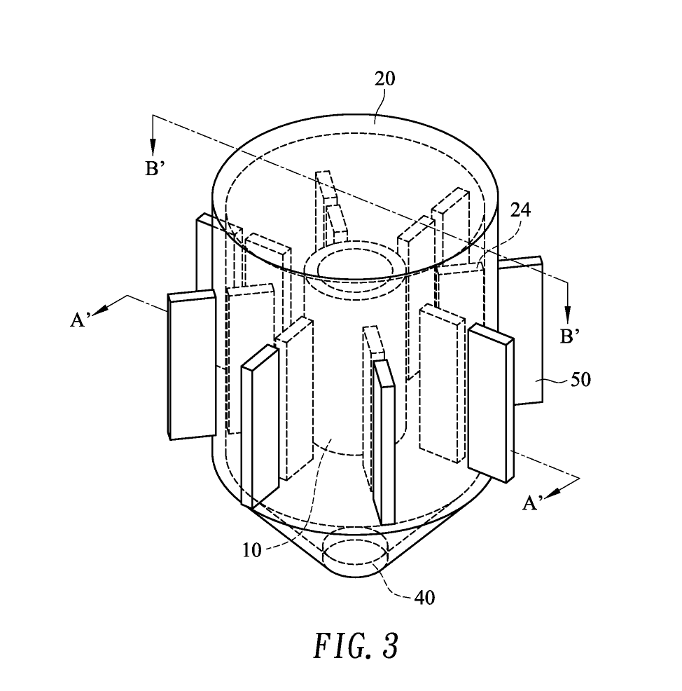

As shown in FIGS. 1 to 4C, an embodiment of the present invention provides a cooling apparatus using solid-liquid phase change material. The cooling apparatus includes: a pipeline 10; a housing 20; and a solid-liquid phase change material (PCM) 30. The cooling apparatus makes contact with the heat source 40 to help heat source 40 dissipate heat. The heat source 40 can be a CPU module, an IC module, a power chip, an LED lamp, a fin of an LED lamp or a lithium battery.

The housing 20 completely encloses the pipeline 10, and the solid-liquid PCM 30 is filled in the housing 20 and a space between the housing 20 and the pipeline 10. When the heat source 40 generates heat, the solid-liquid PCM 30 absorbs the heat and uses the heat as a latent heat for phase changing. The solid-liquid PCM 30, which is changed from a solid state to a liquid state, flows to dissipate the heat by thermal convection.

The pipeline 10 is a pipe with an upper end and a lower end, and each of those ends has a diverting opening 11, respectively. The housing 20 completely encloses the pipeline 10 inside without directly making contact with the pipeline 10. The pipeline 10 can be supported by a frame (not shown) and connect to the housing 20. In order to keep sufficient space for the solid-liquid PCM 30 in the liquid state to flow, the pipeline 10 and the housing 20 need to be spaced a specific distance apart.

In order to make the solid-liquid PCM 30, which is changed to the liquid state, smoothly flow in the housing 20, the shape and the structure of the housing 20 require special designs. For making the housing 20 dissipate the heat generated by the heat source 40 quickly by thermal conduction, the material of the housing 20 can use materials with high heat transfer characteristics. For example, the high heat transfer metal material with a heat transfer coefficient greater than or equal to 150 W/m□K.

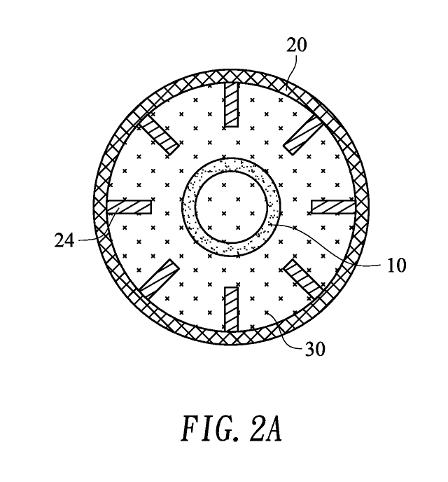

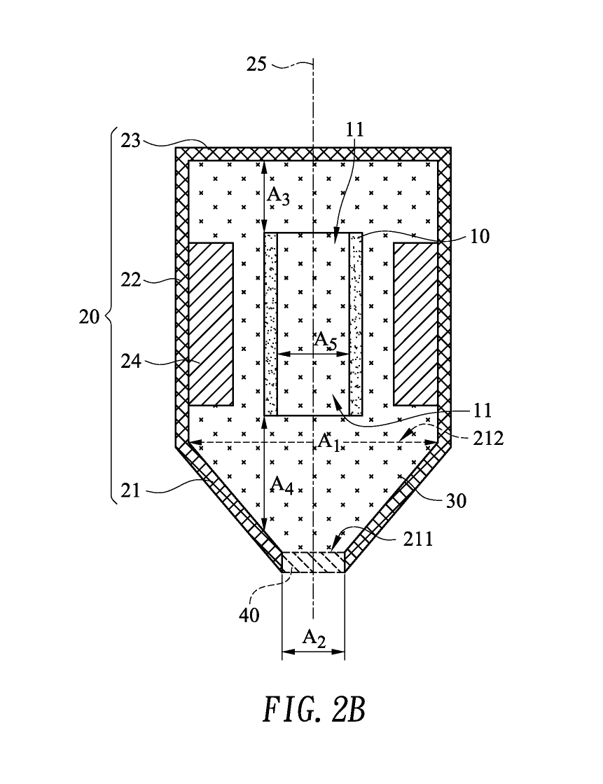

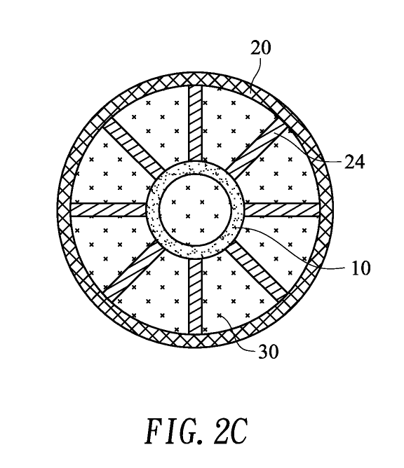

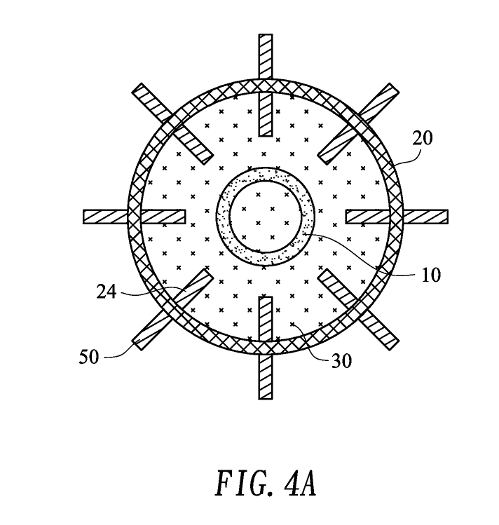

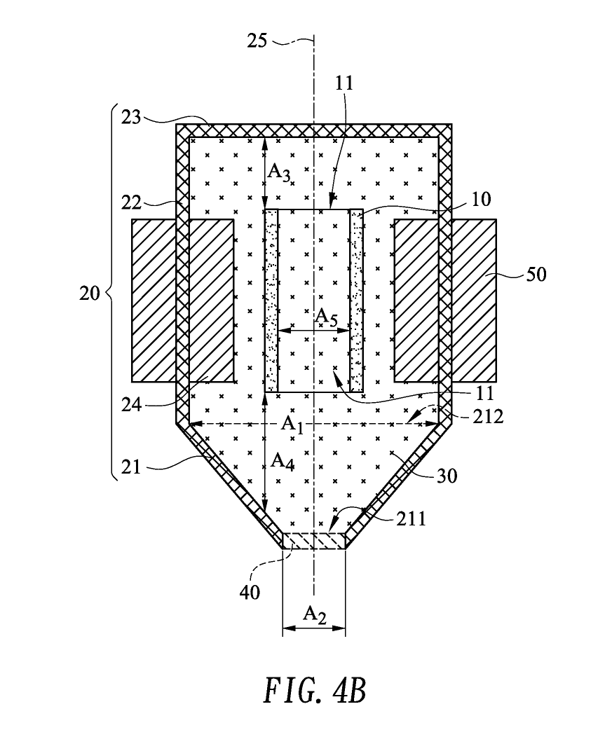

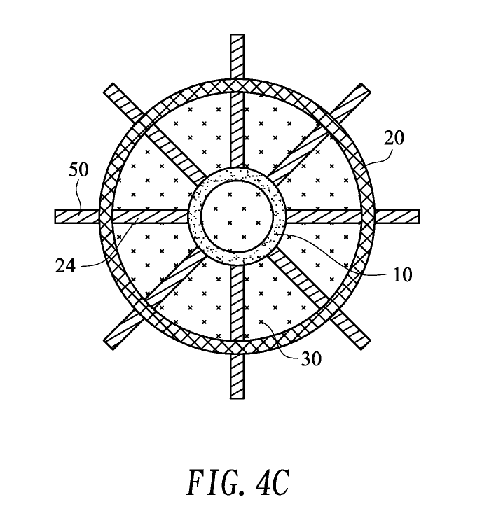

As shown in FIGS. 2B and 4B, the housing 20 has: an inclined diverting portion 21; a vertical portion 22; a sealing portion 23; and a plurality of inner fins 24.

The inclined diverting portion 21 tilts towards an off axis direction from a central axis 25 of the housing 20. Each of two opposite ends of the inclined diverting portion 21 has a heat source opening 211 and a connecting portion opening 212, respectively. The heat source opening 211 receives the heat source 40, so that the heat source 40 can just cover the heat source opening 211 when the heat source 40 is disposed within the heat source opening 211. In this manner, after the housing 20 is in combination with the heat source 40, a completely sealed space is formed for filling the solid-liquid PCM 30 inside and prevents the solid-liquid PCM 30 in the liquid state from flowing out of the housing 20.

The inclined diverting portion 21 needs enough space to guide the solid-liquid PCM 30 substantially to flow towards a specific direction. Therefore, a cross-sectional area A₁ of the connecting portion opening 212 of the inclined diverting portion 21 should be larger than a cross-sectional area A₂ of the heat source opening 211, so that the inclined diverting potion 21 may constitute a quasi cone. The location of the heat source opening 211 is lower than the location of the connecting portion opening 212, and thereby the solid-liquid PCM 30 in the liquid state may flow towards the heat source 40 along an inclined direction of the inclined diverting portion 21. In order to keep a sufficient distance between the pipeline 10 and the heat source 40, a location of the connecting portion opening 212 should be lower than locations of the diverting openings 11.

The vertical portion 22 connects to the inclined diverting portion 21 at the connecting portion opening 212 and extends away from the heat source opening 211. The vertical portion 22 is used as the side wall of the housing 20, and the sealing portion 23 is connected to the vertical portion 22 and covers an opening formed by the vertical portion 22. In other words, the sealing portion 23 and the inclined diverting portion 21 are connected to both sides of the vertical portion 22, respectively. In addition, there is a gap between the sealing portion 23 and the pipeline 10 to facilitate the filling of the solid-liquid PCM 30, and the solid-liquid PCM 30 in the liquid state can flow in the gap between the sealing portion 23 and the pipeline 10.

As illustrated in FIGS. 2A and 4A, the vertical portion 22 is connected with a plurality of inner fins 24, so that the heat can not only be dissipated outwards through the housing 20, but can also be transferred to the solid-liquid PCM 30 through the housing 20 and the inner fins 24. Since the plurality of inner fins 24 can further increase the contact area of the solid-liquid PCM 30 and the housing 20, the heat exchange rate is thereby accelerated.

As shown in FIGS. 1 to 4C, the inner fins 24 are disposed to extend towards in the direction of the central axis 25 of the housing 20, and such that each two of the inner fins 24 form an internal flow channel therebetween. A direction of the internal flow channel is parallel to the central axis 25 of the housing 20 to allow the solid-liquid PCM 30 in the liquid state to flow inside. As shown in FIGS. 2A and 4A, the inner fins 24 may not extend to the pipeline 10. However, as shown in FIGS. 2C and 4C, the inner fins 24 can also extend to the pipeline 10 and connect to the pipeline 10.

In addition, since the cooling apparatus as a whole needs to dissipate the heat to the external environment, the cooling apparatus may further comprise a plurality of outer fins 50 in addition to the inner fins 24 to dissipate the heat to the external environmental in a more efficient way. Similarly, the outer fins 50 are connected to the vertical portion 22 and extend outwardly of the housing 20. Each two of the outer fins 50 form an external flow channel therebetween, and a direction of the external flow channel is parallel to the central axis 25 of the housing 20 to increase the contact area with the external environment.

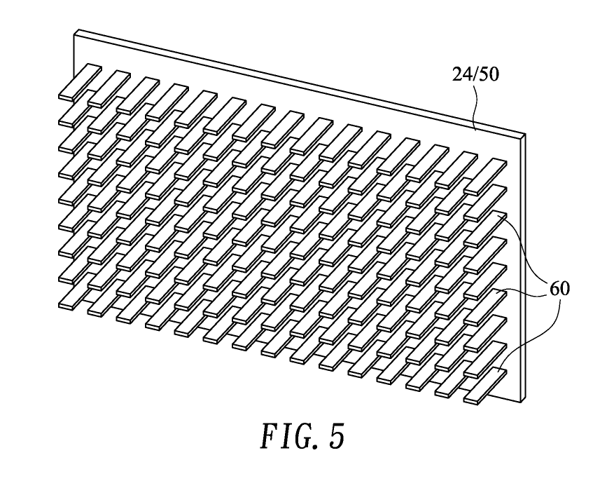

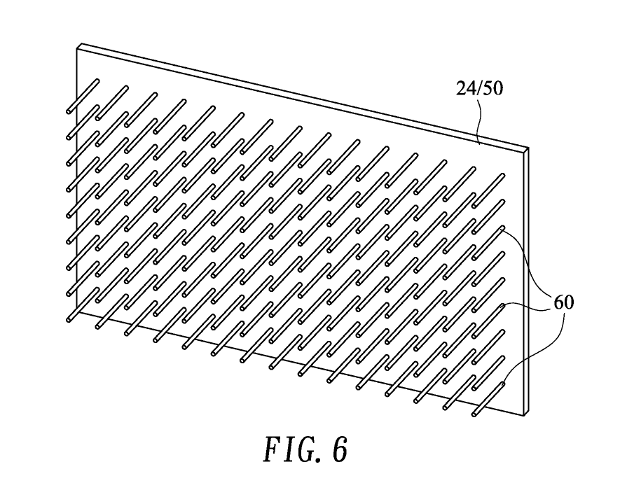

As shown in FIGS. 5 and 6, in order to further increase the contact area with the solid-liquid PCM 30 or with the external environment, the inner fins 24 or the outer fins 50 can be further disposed with a plurality of projecting portions 60. The projecting portions 60 may be sheet-like or in a columnar shape. Some possible foi is are listed here, but the implementation is not limited to these.

As shown in FIGS. 1 to 4C, the solid-liquid PCM 30 is filled in the pipeline 10 and the space between the pipeline 10 and the housing 20, and its melting point is below an operating temperature of the heat source 40. The solid-liquid PCM 30 may be filled in the form of particles inside the pipeline 10 and the space between the pipeline 10 and the housing 20, or be poured in after being welded.

The solid-liquid PCM 30 may be alkali nitrates, sodium acetate, sodium metasilicate pentahydrate (Na₂SiO₃□5H₂O) metal or alkane mixtures. For example, paraffin wax can be used as the solid-liquid PCM 30. The latent heat of the solid-liquid PCM 30 is the bigger the better; preferably the latent heat is greater than 100 J/g.

As the solid-liquid PCM 30 needs to absorb a lot of heat (i.e. heat of fusion) during the phase change and the temperature of the solid-liquid PCM 30 during the melting process is almost constant or only changes a small amount, the embodiments of the present invention use the characteristics of the solid-liquid PCM 30, which absorbs a large amount of heat without increasing the temperature, to make the heat source 40 and the solid-liquid PCM 30 make thermal contact with each other directly to dissipate heat to stabilize the temperature of the heat source 40 (for example, power electronics). By carefully selecting the physical properties of the solid-liquid PCM 30, the temperature of the heat source 40 can be maintained lower than its working temperature, and the heat source 40 would be in a state with sufficient using time.

Throughout the process, the working process of the cooling apparatus is divided into a heating stage and a cooling stage. The heating stage is divided into three sub-stages, corresponding to whether the solid-liquid PCM 30 is in a pure solid state, a phase transition state, and a pure liquid state. The cooling stage can be divided into two sub-stages, corresponding to whether the solid-liquid PCM 30 is in a pure liquid state or a pure solid state.

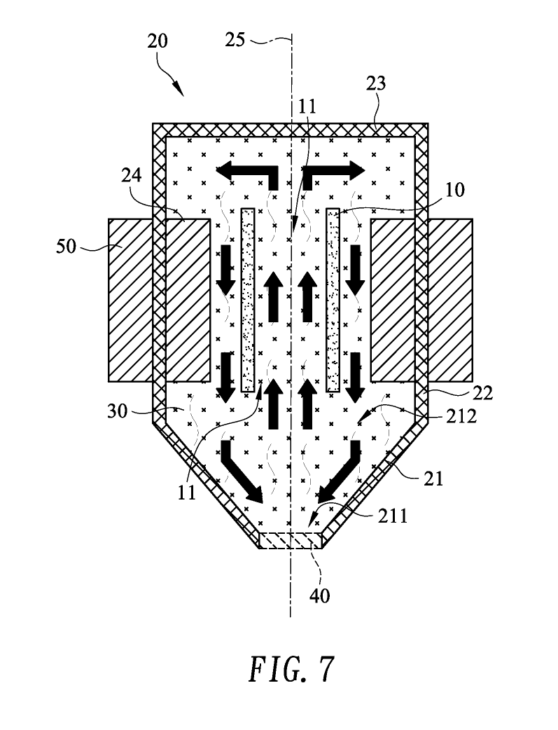

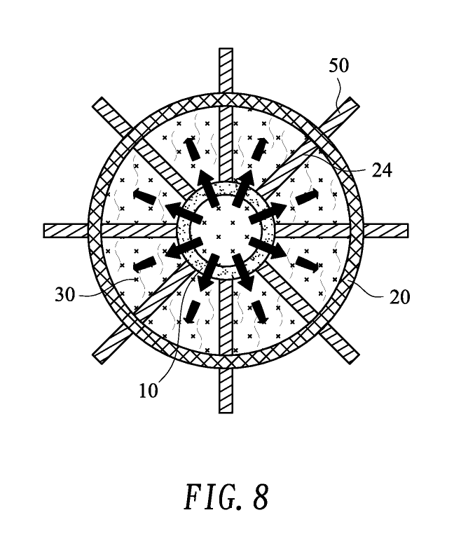

As shown in FIGS. 7 and 8, in the pure solid state of the heating stage, the heat source 40 disposed in the heat source opening 211 directly makes contact with the solid-liquid PCM 30, so that the heat source 40 can directly heat the solid-liquid PCM 30 when the heat source 40 starts to generate heat. However, the solid-liquid PCM 30 is still in the pure solid state at this time because the temperature has not exceeded the melting point of the solid-liquid PCM 30. The solid-liquid PCM 30 absorbs heat and transfers the heat to the housing 20 by theiinal conduction to achieve an initial cooling effect.

Then in the phase transition state of the heating stage, the solid-liquid PCM 30 on the heat exchange surface between the heat source 40 and the solid-liquid PCM 30 gradually changes from a solid state to a liquid state, but its temperature is maintained substantially constant. The heat absorbed by the solid-liquid PCM 30 becomes a latent heat required for the phase change. The temperature only rises a little bit until all the solid-liquid PCM 30 is changed to the liquid state.

Then, in the pure liquid state of the heating stage, the solid-liquid PCM 30 continuously absorbs heat and the temperature continuously rises. Because the solid-liquid PCM 30 has changed to the pure liquid state, the cooling mechanism further comprises thermal convection phenomena in addition to thermal conduction.

The solid-liquid PCM 30, which is heated and in the liquid state, starts to flow from the heat source opening 211, which is closest to the heat source 40, towards the diverting opening 11 adjacent to the connecting portion opening 212. Then it flows through the pipeline 10 and flows out from the other end of the diverting opening 11, later it flows outwards into the space between the pipeline 10 and the housing 20, and it flows back to the heat source opening 211 through the guidance of the inclined surface of the inclined diverting portion 21.

Because the temperature of the solid-liquid PCM 30 will drop slightly when it flows to a place far away from the heat source 40, the solid-liquid PCM 30 in the liquid state with a lower temperature will be pushed by the solid-liquid PCM 30 in the liquid state with higher temperature and return to the heat source opening 211. Such thermal convection circulation can speed up the dissipation rate.

In particular, please refer to FIGS. 2B and 4B at the same time, a phantom line is provided from the outermost edge of the pipeline 10 vertically towards the inclined diverting portion 21 and the sealing portion 23 until the phantom line intersects at a point with the inclined diverting portion 21 and the sealing portion 23, respectively. The phantom line forms an upper phantom tubular body and a lower phantom tubular body in the upper side and the lower side of the pipeline 10.

The longitudinal cross-sectional area A₃ of the upper phantom tubular body formed by said phantom line in the upper side of the pipeline 10 (i.e. the cross-sectional area formed by the upper end of pipeline 10 and the sealing portion 23 in the vertical direction) may be greater than or equal to the cross-sectional area A₅ of the diverting opening 11. The longitudinal cross-sectional area A₄ of the lower phantom tubular body formed by said phantom line in the lower side of the pipeline 10 (i.e. the cross-sectional area formed by the lower end of pipeline 10 and the inclined diverting portion 21 in the vertical direction) may be greater than or equal to the cross-sectional area A₅ of the diverting opening 11. Therefore, the speed of the solid-liquid PCM 30 in the liquid state flowing back to the heat source opening 211 is faster than or equal to the speed of the solid-liquid PCM 30 in the liquid state flowing out away from the heat source opening 211, and thereby the speed of flowing back is increased and thermal convection can achieve better results.

And in the pure liquid state of the cooling phase, the solid-liquid PCM 30 will continuously dissipate heat to the housing 20 by thermal convection and thermal conduction. However, the solid-liquid PCM 30 may be in a supercooled state. When the temperature of the solid-liquid PCM 30 is below the melting point, it can still keep in the liquid state. The heat is still continuously dissipated by thermal convection and the temperature of the solid-liquid PCM 30 can keep cooling more efficiently at low temperature.

In the pure solid state of the cooling stage, because the cooling apparatus keeps cooling the heat source 40 and under the continuous cooling condition, the solid-liquid PCM 30 will condense back to the solid state and continuously dissipate heat by thermal conduction until the heat source 40 and the cooling apparatus and the external environment are in temperature balance with each other.

Regardless of which one of the above stages and the cooling apparatus is in, the heat absorbed by the solid-liquid PCM 30 is still continuously dissipated to the external environment through the housing 20.

In addition, the heat source 40 may have two operating modes, one is continuously operating to generate heat, and the other one is continuously generating heat for a period of time while the other period of time is for heat dissipation. The former, for example, is a generator which is for a long term without being shut down, and the later, for example, is a street light usually operating at night.

As the solid state heat transfer characteristics of the solid-liquid PCM 30 is far superior to those of air, the solid-liquid PCM 30 in the liquid state not only cools by thermal conduction but also cools by thermal convection. Therefore, the cooling apparatus of the present embodiment of the invention provides better cooling capability to the heat source 40 than other passive cooling devices. Furthermore, the embodiments of the invention applied in some cooling mechanisms only absorb heat over a short time. The phase change material in the high-temperature phase can dissipate heat slowly while the heat source is not in use over a long time, thereby to achieve greater thermal efficiency.

The present invention has been described with reference to the preferred embodiments and it is understood that the embodiments are not intended to limit the scope of the present invention. Moreover, as the contents disclosed herein should be readily understood and can be implemented by a person skilled in the art, all equivalent changes or modifications which do not depart from the concept of the present invention should be encompassed by the appended claims.

What is claimed is:

1. A cooling apparatus using solid-liquid phase change material (solid-liquid PCM), the solid-liquid phase change cooling apparatus making contact with a heat source and comprising:
a pipeline having an upper end and a lower end, each of the upper end and the lower end having a diverting opening, respectively;
a housing completely enclosing the pipeline without directly making contact with the pipeline, the housing having:
an inclined diverting portion tilting towards an off axis direction from a central axis of the housing, each of two opposite ends of the inclined diverting portion having a heat source opening and a connecting portion opening respectively, a cross-sectional area of the connecting portion opening is larger than a cross-sectional area of the heat source opening, a location of the connecting portion opening is lower than locations of the diverting openings, a location of the heat source opening is lower than the location of the connecting portion opening, the heat source being disposed at the heat source opening and covering the heat source opening;
a vertical portion connecting to the inclined diverting portion at the connecting opening portion and extending away from the heat source opening;
a sealing portion connecting to the vertical portion and covering an opening formed by the vertical portion, a gap being defined between the sealing portion and the pipeline; and
a plurality of inner fins connecting to the vertical portion and extending towards the central axis of the housing; and
a solid-liquid phase change material filling in an interior of the pipeline and a space between the pipeline and the housing, a melting point of the solid-liquid phase change material being below the operating temperature of the heat source;
wherein the solid-liquid phase change material absorbs heat energy generated by the heat source and is changed from a solid state to a liquid state, the solid-liquid phase change material in the liquid state flows from the heat source opening towards the diverting opening, which is close to the connecting portion opening, then flows through the pipeline and out of the diverting opening of the other end of the pipeline, flows into the space between the pipeline and the housing and flows back to the heat source opening with the guide of the inclined diverting portion.

2. The cooling apparatus using the solid-liquid PCM as claimed in claim 1, wherein each two of the inner fins form an internal flow channel, and a direction of the internal flow channel is parallel to the central axis of the housing.

3. The cooling apparatus using the solid-liquid PCM as claimed in claim 2, wherein the inner fins extends towards the central axis of the housing to the pipeline and connects to the pipeline.

4. The cooling apparatus using the solid-liquid PCM as claimed in claim 3, further comprising a plurality of outer fins, connecting to the vertical portion and extending toward an outside of the housing.

5. The cooling apparatus using the solid-liquid PCM as claimed in claim 4, wherein each two of the outer fins form an external flow channel, and a direction of the external flow channel is parallel to the central axis of the housing.

6. The cooling apparatus using the solid-liquid PCM as claimed in claim 1, wherein further comprising a plurality of outer fins, connecting to the vertical portion and extending toward an outside of the housing.

7. The cooling apparatus using the solid-liquid PCM as claimed in claim 6, wherein each two of the inner fins form an internal flow channel, each two of the outer fins form an external flow channel, a direction of the internal flow channel and a direction of the external flow channel are both parallel to the central axis of the housing.

8. The cooling apparatus using the solid-liquid PCM as claimed in claim 1, wherein the solid-liquid PCM is alkali nitrates, sodium acetate, sodium metasilicate pentahydrate (Na₂SiO₃□5H₂O) metal or alkane mixtures.

9. The cooling apparatus using the solid-liquid PCM as claimed in claim 8, wherein the solid-liquid PCM is paraffin wax.

10. The cooling apparatus using the solid-liquid PCM as claimed in claim 1, wherein a material of the housing is a high heat transfer metal material with a heat transfer coefficient greater than or equal to 150 W/m*K.

11. The cooling apparatus using the solid-liquid PCM as claimed in claim 1, wherein a cross-sectional area formed by the upper end of the pipeline and the sealing portion in the vertical direction is larger than or equal to a cross-sectional area of the diverting opening, and a cross-sectional area formed by the lower end of the pipeline and the inclined diverting portion in the vertical direction is larger than or equal to a cross-sectional area of the diverting opening.

12. The cooling apparatus using the solid-liquid PCM as claimed in claim 1, wherein the heat source is a CPU module, an IC module, a power chip, a cooling fin of an LED lamps, or a lithium battery.
